(19) United States
(12) Patent Application Publication
(10) Pub. No.: US 2026/0255801 A1
(43) Pub. Date: Aug. 27, 2026

(54) DISPLAY DEVICE AND ELECTRONIC DEVICE HAVING THE DISPLAY DEVICE

(71) Applicant: Samsung Display Co., LTD., Yongin-si (KR)

(72) Inventors: Hyunjun Jeong, Yongin-si (KR); Kyung-Tae Kim, Yongin-si (KR); SANGWOO SOHN, Yongin-si (KR); YEON KEON MOON, Yongin-si (KR); JUN HYUNG LIM, Yongin-si (KR)

(21) Appl. No.: 19/544,532

(22) Filed: Feb. 19, 2026

(30) Foreign Application Priority Data
Feb. 25, 2025 (KR) 10-2025-0024092

(51) Int. Cl. H10K 59/121; H10D 86/40

(52) U.S. Cl. CPC H10K 59/1213; H10D 86/423

(57) ABSTRACT

A display device is provided. The display device includes a substrate including a display area and a non-display area surrounding the display area, a pixel circuit overlapping the display area and including a first thin film transistor including a first semiconductor layer and a first gate electrode, and a driving circuit connected to the pixel circuit, overlapping the non-display area, and including a second thin film transistor including a second semiconductor layer and a second gate electrode. The first semiconductor layer includes a first oxide semiconductor material, the second semiconductor layer includes a second oxide semiconductor material, and an electron mobility of the second thin film transistor is higher than an electron mobility of the first thin film transistor.

### CROSS REFERENCE TO RELATED APPLICATION

This application claims priority to Korean Patent Application No. 10-2025-0024092, filed on February 25, 2025, and all the benefits accruing therefrom under 35 U.S.C. §119, the content of which in its entirety is herein incorporated by reference .

### BACKGROUND

### Field

One or more embodiments relate to a display device and an electronic device including the display device.

### Description of the Related Art

Among display devices, organic light-emitting display devices are attracting attention as next-generation displays for having advantages of wide viewing angles, excellent contrast, and fast response speeds.

Typically, a thin film transistor and an organic light-emitting diode, which is a display element, are formed on a substrate, and the organic light-emitting diode emits light, thereby operating the organic light-emitting display device. These organic light-emitting display devices may be used as display units for small products such as mobile phones, and as display units for large products such as televisions.

### SUMMARY

An object of one or more embodiments is to provide a display device having excellent element characteristics and display quality and an electronic device including the display device.

Additional aspects will be set forth in part in the description which follows and, in part, will be apparent from the description, or may be learned by practice of the presented embodiments of the disclosure.

According to one or more embodiments, a display device is provided, which includes a substrate including a display area and a non-display area surrounding the display area, a pixel circuit overlapping the display area and including a first thin film transistor including a first semiconductor layer and a first gate electrode, and a driving circuit connected to the pixel circuit, overlapping the non-display area, and including a second thin film transistor including a second semiconductor layer and a second gate electrode, where the first semiconductor layer includes a first oxide semiconductor material, the second semiconductor layer includes a second oxide semiconductor material, and an electron mobility of the second thin film transistor is higher than an electron mobility of the first thin film transistor.

In an embodiment, the first semiconductor layer may include a crystalline oxide semiconductor material, and the second semiconductor layer may include an amorphous oxide semiconductor material.

In an embodiment, the first semiconductor layer and the second semiconductor layer may be arranged in a same layer.

In an embodiment, the first thin film transistor may further include a third semiconductor layer disposed on the first semiconductor layer.

In an embodiment, the third semiconductor layer and the second semiconductor layer may include a same material.

In an embodiment, the third semiconductor layer may include an amorphous oxide semiconductor material, and the first semiconductor layer may include a crystalline oxide semiconductor material.

In an embodiment, the third semiconductor layer may overlap the first semiconductor layer.

In an embodiment, a width of the third semiconductor layer may be smaller than a width of the first semiconductor layer.

In an embodiment, a thickness of the third semiconductor layer and a thickness of the first semiconductor layer may be equal to each other.

In an embodiment, a thickness of the third semiconductor layer and a thickness of the second semiconductor layer may be equal to each other, and the thickness of the second semiconductor layer may be smaller than a thickness of the first semiconductor layer.

In an embodiment, a width of the third semiconductor layer may be smaller than a width of the first semiconductor layer and larger than a width of the first gate electrode.

In an embodiment, the first thin film transistor may be a driving thin film transistor of the pixel circuit.

In an embodiment, each of the first semiconductor layer and the second semiconductor layer may include indium, and an indium content of the first semiconductor layer may be greater than an indium content of the second semiconductor layer.

According to one or more embodiments, a display device is provided, which includes a substrate including a display area and a non-display area surrounding the display area, a pixel circuit overlapping the display area, and a light-emitting element electrically connected to the pixel circuit and generating light, where the pixel circuit includes a driving transistor including a drain electrode connected to a first node, a gate electrode connected to a second node, and a source electrode connected to a third node, a switching transistor applying a data signal to the first node in response to a scan signal, and an initialization transistor applying an initialization voltage to the second node in response to an initialization control signal, and the driving transistor includes a first semiconductor layer including a crystalline oxide semiconductor material.

In an embodiment, the first semiconductor layer may include indium, and an indium content of the first semiconductor layer may be greater than or equal to 80 at%.

In an embodiment, the driving transistor may further include a third semiconductor layer arranged on the first semiconductor layer, and the third semiconductor layer may include an amorphous oxide semiconductor material.

In an embodiment, a thickness of the third semiconductor layer and a thickness of the first semiconductor layer may be equal to each other.

In an embodiment, a thickness of the third semiconductor layer may be smaller than a thickness of the first semiconductor layer.

In an embodiment, a width of the third semiconductor layer may be smaller than a width of the first semiconductor layer.

In an embodiment, the display device may further include a driving circuit overlapping the non-display area and including an output transistor, and where the output transistor may include a second semiconductor layer including an amorphous oxide semiconductor material.

According to one or more embodiments, an electronic device including a display device is provided, where the display device includes a substrate including a display area and a non-display area surrounding the display area, a pixel circuit overlapping the display area and including a first thin film transistor including a first semiconductor layer and a first gate electrode, and a driving circuit connected to the pixel circuit, overlapping the non-display area, and including a second thin film transistor including a second semiconductor layer and a second gate electrode, wherein the first semiconductor layer includes a first oxide semiconductor material, the second semiconductor layer includes a second oxide semiconductor material, and an electron mobility of the second thin film transistor is higher than an electron mobility of the first thin film transistor.

In an embodiment, the first semiconductor layer may include a crystalline oxide semiconductor material, and the second semiconductor layer may include an amorphous oxide semiconductor material.

According to one or more embodiments, an electronic device including a display device is provided, where the electronic device includes a substrate including a display area and a non-display area surrounding the display area, a pixel circuit overlapping the display area, and a light-emitting element electrically connected to the pixel circuit and generating light, the pixel circuit includes a driving transistor including a drain electrode connected to a first node, a gate electrode connected to a second node, and a source electrode connected to a third node, a switching transistor applying a data signal to the first node in response to a scan signal, and an initialization transistor applying an initialization voltage to the second node in response to an initialization control signal, where the driving transistor includes a first semiconductor layer including a crystalline oxide semiconductor material.

Other aspects, features and advantages other than those described herein will become apparent from the following drawings, claims and detailed description.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a schematic plan view of a display device according to an embodiment.

FIG. 2 is a schematic diagram of an equivalent circuit of one pixel according to an embodiment.

FIG. 3 is a cross-sectional view illustrating examples of planes cut along lines A-A’ and B-B’ of FIG. 1.

FIG. 4 is a cross-sectional view of a display device according to another embodiment.

FIG. 5 is a cross-sectional view of a display device according to another embodiment.

FIG. 6 is a cross-sectional view of a display device according to another embodiment.

FIG. 7 is a cross-sectional view of a display device according to another embodiment.

FIGS. 8A to 8H are cross-sectional views illustrating a method of manufacturing a display device according to an embodiment.

FIG. 9 is a block diagram of an electronic device according to an embodiment.

FIG. 10 is a schematic diagram of electronic devices according to various embodiments.

### DETAILED DESCRIPTION

The present disclosure may have various modifications and embodiments, and specific embodiments are illustrated in the drawings and described in detail in the detailed description. The effects and features of the present disclosure and the methods for achieving them will become apparent with reference to the embodiments described herein in detail together with the drawings. However, the present disclosure is not limited to the embodiments disclosed below and may be implemented in various forms.

In the embodiments below, the terms such as "first" or "second" are not used in a limiting sense but are used for the purpose of distinguishing one component from another.

In the embodiments below, singular expressions include plural expressions unless the context clearly indicates otherwise.

In the embodiments below, terms such as “include” or “have” mean that a feature or component described in the specification is present, and do not exclude in advance the possibility that one or more other features or components may be added.

In the embodiments below, when various components such as layers, films, regions, and plates are said to be “on” or “over” other components, this includes not only cases where they are “directly over” other components, but also cases where other components are interposed between them.

It is to be understood that characteristics described herein with respect to relative terms such as, for example, “high,” “low,” and the like may refer to the characteristics satisfying (e.g., being greater than, less than, or the like) a threshold associated with the characteristics or may refer to a relative level of the characteristics.

In the examples below, terms such as connect or combine do not necessarily imply a direct and/or fixed connection or combination of two members, unless the context clearly indicates otherwise, and do not exclude the presence of another member between the two members.

In the drawings, components may be exaggerated or reduced in size for convenience of explanation. For example, the size and/or thickness of each component illustrated in the drawings are arbitrarily illustrated for convenience of explanation, and thus the present disclosure is not necessarily limited to what is illustrated.

In some embodiments, where the implementation is otherwise feasible, specific process sequences may be performed in a different order than described. For example, two processes described sequentially may be performed substantially simultaneously, or may proceed in the reverse order from that described.

Hereinafter, example embodiments of the present disclosure will be described in detail with reference to the attached drawings. In an example in which describing with reference to the drawings, identical or corresponding components are given the same drawing reference numerals and redundant descriptions thereof will be omitted.

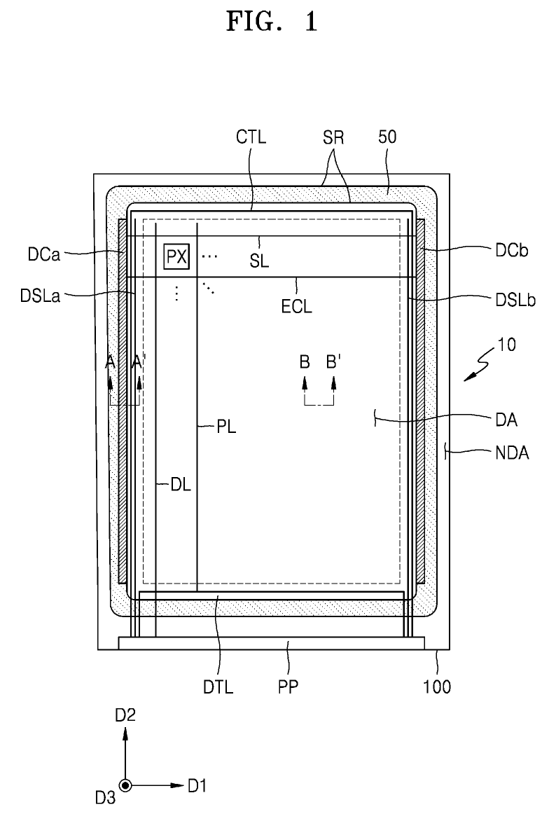

FIG. 1 is a schematic plan view of a display device 10 according to an embodiment.

Referring to FIG. 1, the display device 10 may be applied to various electronic devices such as small and medium-sized electronic devices (e.g., tablet personal computers, smart phones, car navigation units, cameras, center information displays (CIDs) provided in cars, wristwatch-type electronic devices, personal digital assistants (PDAs), portable multimedia players (PMPs), game consoles), medium and large-sized electronic devices (e.g., televisions, outdoor billboards, monitors, personal computers, notebook computers), or the like. However, these are presented as example embodiments, and it is obvious that they can be adopted in other electronic devices without departing from the concept of the present invention.

The display device 10 includes a display panel providing a display screen. The display panel may include an inorganic light-emitting diode display panel, an organic light-emitting display panel, a quantum dot light-emitting display panel, a plasma display panel, a field emission display panel, or the like. Below, organic light-emitting diode display panels are used as embodiments of the display panel, but embodiments of the present disclosure are not limited thereto, and other display panels may be used as embodiments if the same technical idea is applicable.

The display device 10 may include a display area DA and a non-display area NDA surrounding the display area DA. The display area DA is an area where a screen may be displayed, and the non-display area NDA may be an area where a screen is not displayed and where components and/or wires for generating and/or transmitting various signals applied to the display area DA are placed. In FIG. 1, an area inside a boundary line of a square indicated by a dotted line corresponds to the display area DA, and an area outside the boundary line corresponds to the non-display area NDA. The display area DA may generally occupy a center of the display device 10.

The display area DA may include a plurality of pixels PXs. The plurality of pixels PXs may be arranged in a matrix direction on a substrate 100. The shape of each pixel PX may be a rectangle or a square on a plane, but is not limited thereto, and may also be a rhombus with each side tilted in one direction. Each pixel PX may be arranged alternately in stripe type or pentile type. In some aspects, each of the pixel PXs may display a specific color by including one or more light-emitting components that emit light of a specific wavelength.

In the display area DA, signal lines such as scan lines (also called gate lines) SLs, emission control lines ECLs, data lines DLs, and driving voltage lines PLs are also arranged on the substrate 100. The scan lines SLs and the emission control lines ECLs may extend primarily in a first direction D1, and the data lines DLs and the driving voltage lines PLs may extend in a second direction D2 intersecting the first direction D1. Each pixel PX is connected to a scan line SL, an emission control line ECL, a data line DL and a driving voltage line PL, and may receive a scan signal (also called a gate signal), an emission control signal, a data signal and a driving voltage ELVDD from these signal lines, respectively.

In the non-display area NDA, a pad portion PP including pads (not illustrated) for receiving signals from an outside of the display device 10 is located on the substrate 100. The pad portion PP may be located at a lower end portion of the display device 10 as illustrated, but is not limited thereto. The pads of the pad portion PP are electrically connected to the wires arranged in the non-display area NDA. A flexible printed circuit film (not illustrated) capable of transmitting signals and voltages received from the outside may be bonded to the pad portion PP.

A driving device that generates and/or processes various signals for driving pixels PXs of the display area DA may be located in the non-display area NDA and may be located on the flexible printed circuit film bonded to the pad portion PP. The driving device may include a data driver for applying the data signal to the data lines DLs, a scan driver for applying the scan signal to the scan lines SLs, an emission driver for applying the emission control signal to the emission control lines ECLs, and a signal controller for controlling the data driver, the scan driver and the emission driver.

The scan driver and the emission driver are integrated as driving circuits DCa and DCb in the non-display area NDA of the display device 10. The driving circuits DCa and DCb may include a driving circuit DCa located on a left side of the display area DA and a driving circuit DCb located on a right side of the display area DA, and may be extended in the second direction D2. Each of the driving circuits DCa and DCb may include the scan driver and/or the emission driver. Additional or alternative to the example illustrated, the driving circuits DCa and DCb may be located on a single side of the display area DA. The driving circuits DCa and DCb may be electrically connected to the scan lines SLs and the emission control lines ECLs. The driving circuits DCa and DCb may include a shift register including cascaded stages that are dependently connected, each stage including a plurality of transistors and at least one capacitor. Each stage may receive driving circuit signals and generate and output gate signals and/or emission control signals.

The data driver and the signal controller may be provided as integrated circuit chips. The integrated circuit chip may be electrically connected to the display device 10 or mounted on the display device 10 in a tape carrier package TCP. The data driver and signal controller may be formed into a single chip or into separate chips.

Driving signal lines DSLa and DSLb, which transmit the driving circuit signals for operating the driving circuits DCa and DCb to the driving circuits DCa and DCb, are located in the non-display area NDA. The driving signal lines DSLa and DSLb may include driving signal lines DSLa located on a left side of the display area DA and driving signal lines DSLb located on a right side of the display area DA. To avoid complicating the drawing, the driving signal lines DSLa and DSLb are depicted as a single line in FIG. 1, however, the driving signal lines DSLa and DSLb may include a number of signal lines corresponding to a number of signals applied to the driving circuits DCa and DCb, or may include more or fewer signal lines. The driving signal lines DSLa and DSLb are electrically connected to the pad portion PP and may be extended in the second direction D2 parallel to the driving circuits DCa and DCb between the driving circuits DCa and DCb and the display area DA.

The driving circuit signals transmitted from the pad portion PP to the driving circuits DCa and DCb via the driving signal lines DSLa and DSLb may include scan clock signals, emission clock signals, gate low voltage VGL, gate high voltage VGH, scan frame signal (also called vertical start signal STV), emission frame signal, or the like. The scan clock signals, the gate low voltage VGL and the gate high voltage VGH may be transmitted to the scan drivers of the driving circuits DCa and DCb and used to generate the scan signals. The emission clock signals, the gate low voltage VGL and the gate high voltage VGH may be transmitted to the emission drivers of the driving circuits DCa and DCb and used to generate the emission control signals. The scan frame signal may be transmitted to the scan driver to command a start of a frame for inputting the scan signal to the display area DA, and the emission frame signal may be transmitted to the emission driver to command a start of a frame for inputting the emission control signal to the display area DA.

A common voltage transmission line CTL to supply common voltage ELVSS to the pixels PXs is located in the non-display area NDA. The common voltage transmission line CTL may transmit the common voltage ELVSS of a certain level supplied through the pad portion PP to a common electrode of the pixels PXs. The common voltage transmission line CTL may be electrically connected to the pad portion PP at both ends and may be formed to surround the display area DA. On the left and right sides of the display area DA, the common voltage transmission line CTL may be located between the driving circuits DCa and DCb and the driving signal lines DSLa and DSLb.

A driving voltage transmission line DTL to supply the driving voltage ELVDD to the pixels PXs is located in the non-display area NDA. The driving voltage transmission line DTL may be electrically connected to the pad portion PP and the driving voltage line PL, and may be located at the lower side of the display area DA. The driving voltage ELVDD input through the pad portion PP may be applied to the pixels PXs through the driving voltage transmission line DTL and the driving voltage line PL.

The non-display area NDA may include a sealed area SR. The sealed area SR may be separated from the display area DA. A sealant 50 may be arranged in the sealed area SR. The sealant 50 may be formed to completely surround the display area DA. The sealant 50 may at least partially overlap the driving circuits DCa and DCb. For a case in which the sealant 50 overlaps with the driving circuits DCa and DCb, the area of the non-display area NDA on the left and right of the display area DA may be reduced, so the width of the left and right bezels of the display device may be reduced. Portions located outside the sealed area SR at the left edge, the right edge and the upper edge of the display area DA in the substrate 100 may be finally cut off.

Each pixel PX of the display device 10 includes a pixel circuit. The above-described wires may pass through each pixel PX or around each pixel PX to apply driving signals to each pixel circuit. The pixel circuit may include transistors and capacitors, and the transistors may be thin film transistors. The number of transistors and capacitors in each pixel circuit may vary. Below, the pixel circuit is described using a 7T1C structure, which includes 7 transistors and 1 capacitor, as an example, but is not limited thereto and various other modified pixel PX structures such as a 2T1C structure, a 3T1C structure, and a 6T2C structure may be applied.

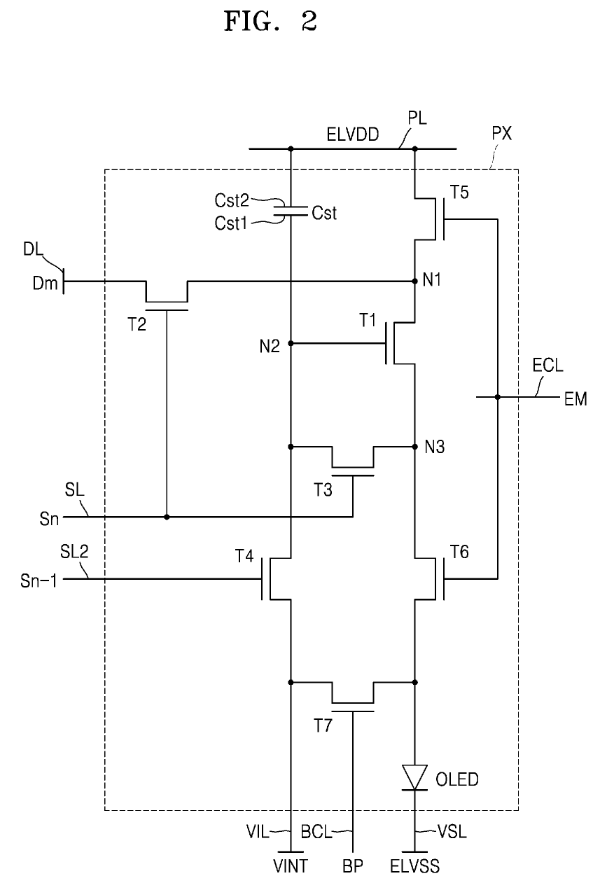

FIG. 2 is a schematic diagram of an equivalent circuit of one pixel according to an embodiment.

Referring to FIG. 2, the pixel PX located in the display area DA in the display device 10 according to an embodiment includes thin film transistors T1 to T7, a maintenance capacitor Cst and an organic light-emitting diode OLED, which are connected to display signal lines SL, SL2, ECL, BCL, DL, PL and VIL.

The thin film transistors T1 to T7 may include a driving transistor T1, a switching transistor T2, a compensation transistor T3, an initialization transistor T4, an operation control transistor T5, a light emission control transistor T6 and a bypass transistor T7.

The display signal lines SL, SL2, ECL, BCL, DL, PL and VIL may include a scan line SL, a preceding scan line SL2, an emission control line ECL, a bypass control line BCL, a data line DL, a driving voltage line PL and an initialization voltage line VIL. The scan line SL and the preceding scan line SL2 are connected to the scan drivers of the driving circuits DCa and DCb and may receive a scan signal Sn and a preceding scan signal Sn-1, respectively, and the emission control line ECL is connected to the emission drivers of the driving circuits DCa and DCb and may receive an emission control signal EM.

The preceding scan line SL2 delivers the preceding scan signal Sn-1 to the initialization transistor T4, the emission control line ECL delivers the emission control signal EM to the operation control transistor T5 and the light emission control transistor T6, and the bypass control line BCL delivers a bypass signal BP to the bypass transistor T7.

The data line DL may receive a data signal Dm, the driving voltage line PL may receive the driving voltage ELVDD, and the initialization voltage line VIL may receive an initialization voltage VINT. The initialization voltage VINT initializes the driving transistor T1.

A gate electrode of the driving transistor T1 is connected to a first end Cst1 of the maintenance capacitor Cst. A drain electrode of the driving transistor T1 is connected to the driving voltage line PL via the operation control transistor T5. A source electrode of the driving transistor T1 is connected to an anode of the organic light-emitting diode OLED via the light emission control transistor T6. The driving transistor T1 controls a driving current supplied to the organic light-emitting diode OLED in response to a potential of a second node N2.

A gate electrode of the switching transistor T2 is connected to the scan line SL. One of a source electrode and a drain electrode of the switching transistor T2 is connected to the data line DL. The other one of the source electrode and the drain electrode of the switching transistor T2 is connected to the drain electrode of the driving transistor T1 and is connected to the driving voltage line PL via the operation control transistor T5. The switching transistor T2 is turned on by the scan signal Sn applied to the scan line SL and provides the data signal Dm applied to the data line DL to a first node N1.

A gate electrode of the compensation transistor T3 is connected to the scan line SL. One of a source electrode and a drain electrode of the compensation transistor T3 is connected to the source electrode of the driving transistor T1 and is connected to the anode of the organic light-emitting diode OLED via the light emission control transistor T6. The other one of the source electrode and the drain electrode of the compensation transistor T3 is connected to a source electrode or a drain electrode of the initialization transistor T4, the first end Cst1 of the maintenance capacitor Cst and the gate electrode of the driving transistor T1.

A gate electrode of the initialization transistor T4 is connected to the preceding scan line SL2. One of the source electrode and the drain electrode of the initialization transistor T4 is connected to the initialization voltage line VIL. The other one of the source electrode and the drain electrode of the initialization transistor T4 is connected to the first end Cst1 of the maintenance capacitor Cst and the gate electrode of the driving transistor T1 through the compensation transistor T3. The initialization transistor T4 is turned on in response to the preceding scan signal Sn-1 applied to the preceding scan line SL2 and provides the initialization voltage VINT to the second node N2. The second node N2 is initialized by the initialization voltage VINT.

A gate electrode of the operation control transistor T5 is connected to the emission control line ECL. One of a source electrode and a drain electrode of the operation control transistor T5 is connected to the driving voltage line PL. The other one of the source electrode and the drain electrode of the operation control transistor T5 is connected to the drain electrode of the driving transistor T1 and is connected to the source electrode or the drain electrode of the switching transistor T2.

A gate electrode of the light emission control transistor T6 is connected to the emission control line ECL. One of a source electrode and a drain electrode of the light emission control transistor T6 is connected to the source electrode of the driving transistor T1 and is connected to the source electrode or the drain electrode of the compensation transistor T3. The other one of the source electrode and the drain electrode of the light emission control transistor T6 is connected to the anode of the organic light-emitting diode OLED.

A gate electrode of the bypass transistor T7 is connected to the bypass control line BCL. One of a source electrode and a drain electrode of the bypass transistor T7 is connected to the source electrode or the drain electrode of the light emission control transistor T6 and is connected to the anode of the organic light-emitting diode OLED. The other one of the source electrode and the drain electrode of the bypass transistor T7 is connected to the initialization voltage line VIL and is connected to the source electrode or the drain electrode of the initialization transistor T4.

A second end Cst2 of the maintenance capacitor Cst is connected to the driving voltage line PL. A cathode of the organic light-emitting diode OLED is connected to a common voltage transmission line VSL transmitting the common voltage ELVSS. The common voltage transmission line VSL or the cathode electrode receives the common voltage ELVSS.

The circuit structure of the pixel PX is not limited to that illustrated in FIG. 2, and the number of transistors, the number of capacitors, and the connections between them may be varied.

In some embodiments, the thin film transistors T1 to T7 may include an oxide semiconductor material. In an embodiment, the thin film transistors T1 to T7 may all be n-channel MOSFETs (NMOSs) including the oxide semiconductor material. However, embodiments of the present disclosure are not limited thereto, and some of the thin film transistors T1 to T7 may be n-channel MOSFET (NMOS) and the rest may be p-channel MOSFET (PMOS).

In the case of oxide semiconductors, a carrier mobility is high and a leakage current is low, so a voltage drop is not large even if an operating time is long. That is, in the case of oxide semiconductors, a color change of the image due to the voltage drop is not large even when driven at low frequencies, so low-frequency driving is possible. Therefore, a display device that prevents leakage current and reduces power consumption may be implemented by having the thin film transistors T1 to T7 include the oxide semiconductor material.

In some embodiments, the oxide semiconductor is sensitive to light, such that external light causes fluctuations in the amount of current, or the like. Therefore, it is possible to consider positioning a metal layer under the oxide semiconductor to absorb or reflect light from the outside. The metal layer located below the oxide semiconductor may overlap with the oxide semiconductor when viewed in a direction perpendicular to an upper surface of the substrate 100 (a direction perpendicular to DR1 and DR2).

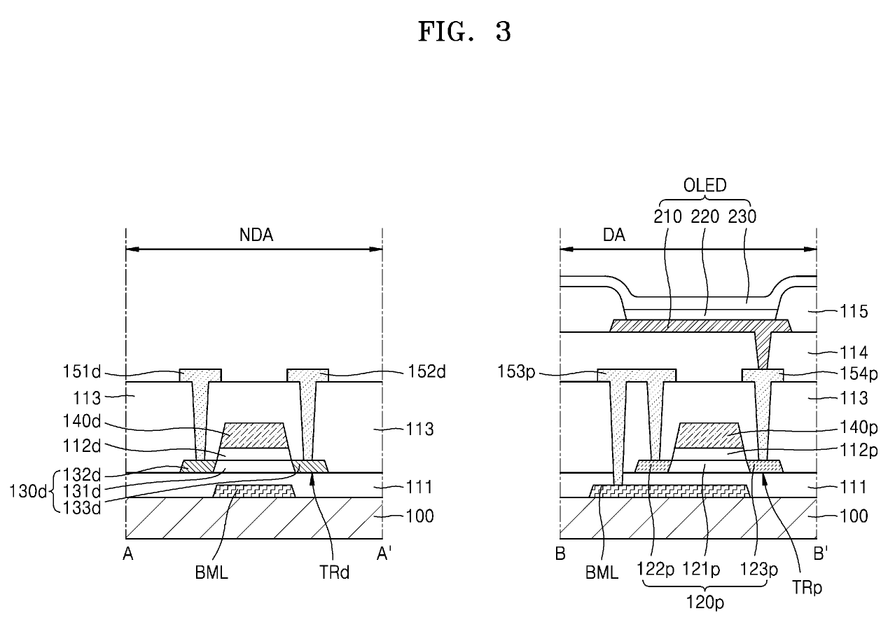

Below, the laminated structure of the display device 10 is described in detail with reference to FIG. 3.

FIG. 3 is a cross-sectional view illustrating examples of planes cut along lines A-A’ and B-B’ of FIG. 1.

Each of the pixel PX of the display area DA and the driving circuit DCa of the non-display area NDA includes a plurality of thin film transistors, and one thin film transistor TRp among the plurality of thin film transistors included in the pixel PX and one thin film transistor TRd among the plurality of thin film transistors included in the driving circuit DCa will be illustrated and explained. For convenience, the thin film transistor TRp of the pixel PX is called a first thin film transistor, and the thin film transistor TRd of the driving circuit DCa is called a second thin film transistor. The illustrated first thin film transistor TRp may be the driving transistor or the light emission control transistor of the pixel PX, and the second thin film transistor TRd may be an output transistor (also known as a buffer transistor) that outputs the scan signal or the emission control signal in the stage.

The substrate 100 may be an insulating substrate including glass, plastic, quartz, ceramic, or the like. For a case in which the substrate 100 includes plastic, the substrate 100 may include polyimide, polyethylene terephthalate (PET), polyethylene naphthalate (PEN), or polycarbonate (PC).

A lower metal layer BML may be placed on the substrate 100. The lower metal layer BML may include a material having light-blocking properties. For example, the lower metal layer BML may be formed as a single layer or multiple layers including one or an alloy of molybdenum (Mo), aluminum (Al), chromium (Cr), gold (Au), titanium (Ti), nickel (Ni), neodymium (Nd), and copper (Cu). The lower metal layer BML may protect a semiconductor layer by blocking light incident from the outside.

In an embodiment, the lower metal layer BML may be electrically conductive. The lower metal layer BML may be electrically connected to one of a source electrode 153p and a drain electrode 154p of the first thin film transistor TRp. The lower metal layer BML may be omitted.

A buffer layer 111 may be placed on the lower metal layer BML. The buffer layer 111 may cover the substrate 100 and the lower metal layer BML. The buffer layer 111 may block impurities that may diffuse from the substrate 100 to the semiconductor layer during a process of forming the semiconductor layer and reduce the stress applied to the substrate 100. The buffer layer 111 may increase an adhesion of the semiconductor layer. The buffer layer 111 is an insulating layer, but considering its functional aspect, the buffer layer 111 is referred to as the buffer layer. The buffer layer 111 may include an inorganic insulating material such as silicon oxide (SiOx) or silicon nitride (SiNx), or the like. For example, the buffer layer 111 may be formed as a multilayer film in which multiple inorganic films are alternately laminated. The buffer layer 111 may be omitted.

The first thin film transistor TRp and the second thin film transistor TRd may be placed on the buffer layer 111. The first thin film transistor TRp may be formed in the display area DA, and the second thin film transistor TRd may be formed in the non-display area NDA. The first thin film transistor TRp may include a first semiconductor layer 120p, a first gate electrode 140p, a first source electrode 153p and a first drain electrode 154p.

The first semiconductor layer 120p may be formed on the buffer layer 111. The first semiconductor layer 120p may have a thickness in a range of 100 Å to 350 Å, preferably in a range of 150 Å to 300 Å.

The first semiconductor layer 120p may include an oxide semiconductor material. The first semiconductor layer 120p may include a crystalline oxide semiconductor material. For example, the oxide semiconductor material included in the first semiconductor layer 120p may include at least one of an InZnO (IZO)-based oxide semiconductor material, an InGaO (IGO)-based oxide semiconductor material, an InGaZnO (IGZO)-based oxide semiconductor material, an InSnO (ITO)-based oxide semiconductor material, an InGaZnSnO (IGZTO)-based oxide semiconductor material, an InSnZnO (ITZO)-based oxide semiconductor material, a ZnO-based oxide semiconductor material, and a FeInZnO (FIZO)-based oxide semiconductor material. However, embodiments of the present disclosure are not limited thereto, and the first semiconductor layer 120p may include other oxide semiconductor materials that have crystallinity and high mobility.

In an embodiment, the first semiconductor layer 120p may include an indium-based oxide semiconductor material having an indium (In) content of 60 atomic% (at%) or more among all metal elements, and may preferably include an indium-based oxide semiconductor material having an indium (In) content of 80 at% or more. For example, the first semiconductor layer 120p may include at least one of an InGaO (IGO)-based oxide semiconductor material, an InZnO (IZO)-based oxide semiconductor material, an InGaZnO (IGZO)-based oxide semiconductor material and an InSnO (ITO)-based oxide semiconductor material, each of which has an indium (In) content of 80 at% or more.

A channel region 131p may have high mobility characteristics because the first semiconductor layer 120p includes a high concentration of indium (In). The first thin film transistor TRp may have excellent electrical characteristics because the first semiconductor layer 120p has the high mobility characteristics.

The first semiconductor layer 120p may be crystallized by a heat treatment process. Specifically, the first semiconductor layer 120p may be formed by deposition and patterning and then crystallized through heat treatment. In an embodiment, the first semiconductor layer 120p may include a crystallization control element that facilitates patterning by preventing crystallization during the deposition process and allowing the first semiconductor layer 120p to be crystallized by a subsequent heat treatment process. The crystallization control element is an element having a strong bonding force with oxygen, and may include at least one of, for example, beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge).

The first semiconductor layer 120p may include a first channel region 121p, a first source region 122p connected to a side of the first channel region 121p, and a first drain region 123p connected to another side of the first channel region 121p. The first source region 122p and the first drain region 123p may be formed by selective conductivity of crystalline oxide semiconductor material. The first channel region 121p may be a non-conductive portion. The first channel region 121p may overlap with the first gate electrode 140p and may overlap with the lower metal layer BML. The first source region 122p and the first drain region 123p may not overlap the first gate electrode 140p.

The first channel region 121p may have a crystalline structure and may be non-conducting because the first semiconductor layer 120p includes crystalline oxide semiconductor material. For example, the first channel region 121p may include at least one crystal structure among a cubic crystal structure, a bixbyte crystal structure, a cubic bixbyte crystal structure, a spinel crystal structure, a hexagonal crystal structure, and a wurtzite crystal structure.

The first channel region 121p may have excellent physical and chemical stability by having the crystalline structure. That is, the first channel region 121p may be prevented from being damaged or its properties from being deformed during the manufacturing process and use of the display device 10. Accordingly, the first thin film transistor TRp, which is the driving transistor of the pixel circuit, may stably control the driving current supplied to the organic light-emitting diode OLED, and the display device 10 including the first thin film transistor TRp has excellent driving stability.

A first gate insulating layer 112p may be placed on the first semiconductor layer 120p. The first gate insulating layer 112p is an insulating layer including an insulating material, and may include at least one of silicon oxide, silicon nitride, and metal oxide. For example, the first gate insulating layer 112p may include an inorganic insulating layer such as silicon oxide, silicon nitride, silicon oxynitride, aluminum oxide, or the like. The first gate insulating layer 112p may have a single-film structure or a multilayer film structure.

The first gate insulating layer 112p may be patterned into a shape corresponding to the first gate electrode 140p. The first gate insulating layer 112p does not cover the first source region 122p and the first drain region 123p, such that an interlayer insulating layer 113 may directly contact the first source region 122p and the first drain region 123p. Therefore, the first source region 122p and the first drain region 123p may be made conductive by hydrogen diffusion from the interlayer insulating layer 113.

However, embodiments of the present disclosure are not limited thereto, and the first gate insulating layer 112p may be formed to cover the buffer layer 111 and the first semiconductor layer 120p.

The first gate electrode 140p may be placed on the first gate insulating layer 112p. The first gate electrode 140p may overlap with the first channel region 121p of the first semiconductor layer 120p. The first gate electrode 140p may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The first gate electrode 140p may have a multilayer film structure including at least two conductive films with different physical properties.

The interlayer insulating layer 113 covers the first semiconductor layer 120p and the first gate electrode 140p, and may be arranged on the buffer layer 111 or the substrate 100. For example, the interlayer insulating layer 113 may include an inorganic insulating material such as silicon oxide, silicon nitride, silicon oxynitride, or aluminum oxide.

The first source electrode 153p and the first drain electrode 154p may be placed on the interlayer insulating layer 113. Each of the first source electrode 153p and the first drain electrode 154p may include at least one of molybdenum (Mo), aluminum (Al), chromium (Cr), gold (Au), titanium (Ti), nickel (Ni), neodymium (Nd), copper (Cu), and alloys thereof. Each of the first source electrode 153p and the first drain electrode 154p may be formed of a single layer including metal or a metal alloy, or may be formed of multiple layers of two or more layers.

Each of the first source electrode 153p and the first drain electrode 154p may be connected to the first semiconductor layer 120p through contact holes. Specifically, the first source electrode 153p and the first drain electrode 154p may be spaced apart from each other and connected to the first source region 122p and the first drain region 123p of the first semiconductor layer 120p, respectively. The first source electrode 153p and the first drain electrode 154p may transmit electrical signals to the first channel region 121p. In an embodiment, the first source electrode 153p or the first drain electrode 154p may be connected to the lower metal layer BML through a contact hole.

In the embodiments and drawings, the first source electrode 153p and the first drain electrode 154p are distinguished for convenience of explanation, and the first source electrode 153p and the first drain electrode 154p are not limited by the drawings and the above explanations. The first source electrode 153p and the first drain electrode 154p may be interchanged.

A planarization layer 114 may be positioned on the interlayer insulating layer 113 by covering the first source electrode 153p and the first drain electrode 154p. The planarization layer 114 may eliminate and flatten steps to increase luminous efficiency of the organic light-emitting diode OLED formed thereon. The planarization layer 114 may include an organic insulating material. For example, the planarization layer 114 may include polyimide, polyamide, polyacrylate, polyphenylene ether, polyphenylene sulfide, unsaturated polyester, epoxy resin, phenol resin, or the like.

The organic light-emitting diode OLED may be placed on the planarization layer 114. The organic light-emitting diode OLED may include a pixel electrode 210, an intermediate layer 220 including a light-emitting layer, and a counter electrode 230. Here, the pixel electrode 210 may be an anode, which is a hole injection electrode, and the counter electrode 230 may be a cathode, which is an electron injection electrode. As another example, the pixel electrode 210 may be the cathode and the counter electrode 230 may be the anode.

The pixel electrode 210 may be a (semi)transparent electrode or a reflective electrode. For example, the pixel electrode 210 may include a reflective layer including Ag, Mg, Al, Pt, Pd, Au, Ni, Nd, Ir, Cr, and compounds thereof, and a transparent or semitransparent electrode layer positioned on the reflective layer. The transparent or semitransparent electrode layer may include at least one selected from a group including indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 210 may have a three-layer structure of ITO / Ag / ITO.

A pixel definition layer 115 may be placed on the planarization layer 114. The pixel definition layer 115 may prevent arcing from occurring at an edge of the pixel electrode 210 by increasing a distance between the edge of the pixel electrode 210 and the counter electrode 230 above the pixel electrode 210. The pixel definition layer 115 includes one or more organic insulating materials selected from a group including polyimide, polyamide, acrylic resin, benzocyclobutene, and phenol resin, and may be formed by a method such as spin coating.

At least a portion of the intermediate layer 220 of the organic light-emitting diode OLED may be positioned within an aperture formed by the pixel definition layer 115. A light-emitting area of the organic light-emitting diode OLED may be defined by the aperture.

The intermediate layer 220 may include a light-emitting layer. The light-emitting layer may include an organic material including a fluorescent or phosphorescent material that emits red light, green light, blue light, or white light. The light-emitting layer may be a low-molecular organic material or a high-molecular organic material, and a functional layer such as a hole transport layer (HTL), a hole injection layer (HIL), an electron transport layer (ETL) and an electron injection layer (EIL) may be further optionally arranged below and above the light-emitting layer.

The light-emitting layer may have a patterned shape corresponding to each of the pixel electrodes 210. Layers other than the light-emitting layer included in the intermediate layer 220 may be modified in various ways, such as being integrally formed across multiple pixel electrodes 210.

The counter electrode 230 may be a transparent electrode or a reflective electrode. For example, the counter electrode 230 may be a transparent or semitransparent electrode and may include a metal thin film having a low work function, including Li, Ca, LiF, Al, Ag, Mg, and compounds thereof. In some aspects, the counter electrode 230 may further include a transparent conductive oxide (TCO) film such as ITO, IZO, ZnO, or In₂O₃ positioned on the metal thin film. The counter electrode 230 is formed integrally over the entire surface of the display area DA and may be placed above the intermediate layer 220 and the pixel definition layer 115.

The second thin film transistor TRd is placed in the non-display area NDA and may include a second semiconductor layer 130d, a second gate electrode 140d, a second source electrode 151d, and a second drain electrode 152d.

The second semiconductor layer 130d may be formed in a same layer as the first semiconductor layer 120p of the first thin film transistor TRp. For example, both the first semiconductor layer 120p and the second semiconductor layer 130d may be formed on the buffer layer 111. The second semiconductor layer 130d may have a thickness in a range of 50 Å to 300 Å, preferably in a range of 100 Å to 250 Å.

The second semiconductor layer 130d may include a second channel region 131d, a second source region 132d connected to a side of the second channel region 131d, and a second drain region 133d connected to another side of the second channel region 131d. The second source region 132d and the second drain region 133d may be formed through selective conductivity of semiconductor material, and the second channel region 131d may be a non-conductive portion. The second channel region 131d may overlap the second gate electrode 140d, and the second source region 132d and the second drain region 133d may not overlap the second gate electrode 140d. The second channel region 131d may overlap with the lower metal layer BML. An electron mobility of the second channel region 131d may be higher than an electron mobility of the first channel region 121p of the first semiconductor layer 120p.

The second semiconductor layer 130d may include an oxide semiconductor material. For example, the second semiconductor layer 130d may include at least one of an InZnO (IZO)-based oxide semiconductor material, an InGaO (IGO)-based oxide semiconductor material, an InGaZnO (IGZO)-based oxide semiconductor material, an InSnO (ITO)-based oxide semiconductor material, an InGaZnSnO (IGZTO)-based oxide semiconductor material, an InSnZnO (ITZO)-based oxide semiconductor material, a ZnO-based oxide semiconductor material, and a FeInZnO (FIZO)-based oxide semiconductor material.

The second semiconductor layer 130d may include a different oxide semiconductor material than the first semiconductor layer 120p. For example, the first semiconductor layer 120p may include the InGaO (IGO)-based oxide semiconductor material, and the second semiconductor layer 130d may include the InGaZnSnO (IGZTO)-based oxide semiconductor material.

The second semiconductor layer 130d may include an indium-based oxide semiconductor material having an indium (In) content of 50 at% or more. Preferably, the indium (In) content of the second semiconductor layer 130d may be 60 at% or more. In an embodiment, the indium (In) content of the total metal elements of the second semiconductor layer 130d may be lower than indium (In) content of the first semiconductor layer 120p.

The second semiconductor layer 130d may include an amorphous oxide semiconductor material. That is, the second channel region 131d of the second semiconductor layer 130d may be amorphous. The oxide semiconductor has oxygen vacancies and thus has high electron mobility characteristics even in an amorphous state. As the oxide semiconductor crystallizes, the oxygen vacancies decrease and the electron mobility decreases. That is, the semiconductor layer including the crystalline oxide semiconductor material has lower mobility characteristics than that in the amorphous state.

In the display device 10, the second thin film transistor TRd including the second semiconductor layer 130d including the amorphous oxide semiconductor material is placed on the output transistor of the driving circuit, a high output scan signal or emission control signal may be provided through a thin film transistor having relatively higher electron mobility than the electron mobility of the driving transistor of the pixel circuit, and power consumption of the display device 10 may be reduced. In some aspects, the driving transistor of the pixel circuit may improve the driving stability of the display device 10 by having excellent stability instead of relatively low electron mobility.

A second gate insulating layer 112d may be placed on the second semiconductor layer 130d. The second gate insulating layer 112d is an insulating layer including an insulating material, and may include at least one of silicon oxide, silicon nitride, and metal oxide. The second gate insulating layer 112d may be formed of a same material at a same manufacturing process as the first gate insulating layer 112p.

The second gate insulating layer 112d may be patterned into a shape corresponding to the second gate electrode 140d. In this case, the interlayer insulating layer 113 may directly contact the second source region 132d and the second drain region 133d, and the second source region 132d and the second drain region 133d may be conductive due to hydrogen diffusion from the interlayer insulating layer 113 adjacent to the second source region 132d and the second drain region 133d.

However, embodiments of the present disclosure are not limited thereto, and the second gate insulating layer 112d may be formed to cover both the buffer layer 111 and the second semiconductor layer 130d.

The second gate electrode 140d may be placed on the second gate insulating layer 112d. The second gate electrode 140d may overlap with the second channel region 131d of the second semiconductor layer 130d. The second gate electrode 140d may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The second gate electrode 140d may have a multilayer film structure including at least two conductive films with different physical properties.

The interlayer insulating layer 113 covers the second semiconductor layer 130d and the second gate electrode 140d, and may be disposed on the buffer layer 111 or the substrate 100. The interlayer insulating layer 113 may be integrally formed across the display area DA and the non-display area NDA.

The second source electrode 151d and the second drain electrode 152d may be placed on the interlayer insulating layer 113. Each of the second source electrode 151d and the second drain electrode 152d may include at least one of molybdenum (Mo), aluminum (Al), chromium (Cr), gold (Au), titanium (Ti), nickel (Ni), neodymium (Nd), copper (Cu), and alloys thereof.

Each of the second source electrode 151d and the second drain electrode 152d may be connected to the second semiconductor layer 130d through contact holes. For example, the second source electrode 151d and the second drain electrode 152d are spaced apart from each other and may be connected to the second source region 132d and the second drain region 133d of the second semiconductor layer 130d, respectively. The second source electrode 151d and the second drain electrode 152d may transmit electrical signals to the second channel region 131d.

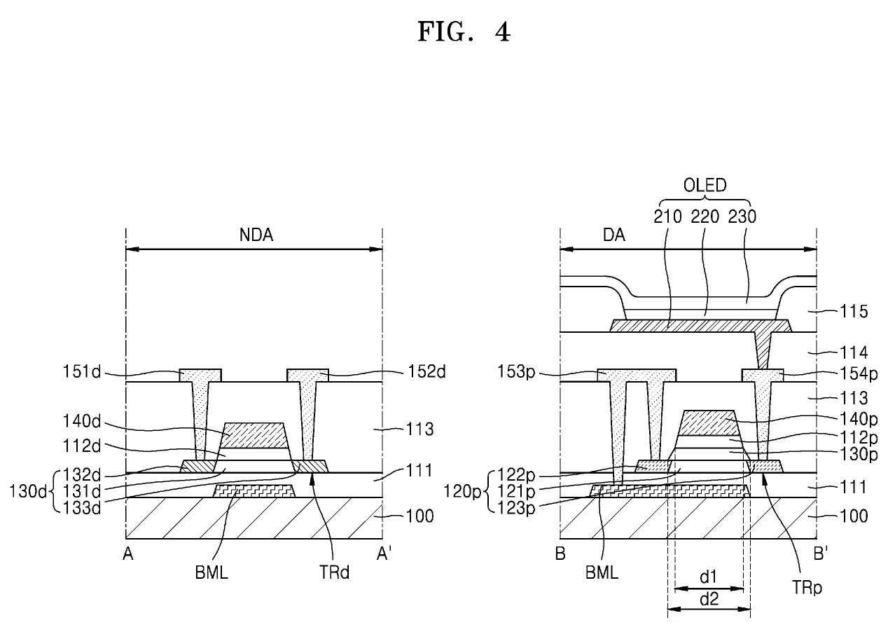

Hereinafter, variations of the display device 10 will be described with reference to FIGS. 4 to 7, and the same configuration as the display device 10 described with reference to FIGS. 1 to 3 will be described using the same drawing numbers.

FIG. 4 is a cross-sectional view of a display device 10 according to another embodiment. A first thin film transistor TRp of the display device of FIG. 4 is different from the first thin film transistor TRp of the display device 10 of FIG. 3. Below, the differences mentioned above will be explained, and any duplicate explanations will be omitted.

Referring to FIG. 4, the first thin film transistor TRp may include the first semiconductor layer 120p, the first gate electrode 140p, the first source electrode 153p, the first drain electrode 154p, and a third semiconductor layer 130p.

The third semiconductor layer 130p may be formed on the first semiconductor layer 120p. The third semiconductor layer 130p may include an oxide semiconductor material. The third semiconductor layer 130p may be formed amorphously. In an embodiment, the third semiconductor layer 130p may be formed of a same material as the second semiconductor layer 130d of the second thin film transistor TRd. The second semiconductor layer 130d and the third semiconductor layer 130p may be formed of a same material at a same process. A thickness of the third semiconductor layer 130p may be formed to be the same as a thickness of the first semiconductor layer 120p, but is not limited thereto.

The third semiconductor layer 130p may overlap with the first channel region 121p of the first semiconductor layer 120p. A width of the third semiconductor layer 130p may be formed to correspond to the first channel region 121p of the first semiconductor layer 120p. Here, the width is a length of a cross-section cut along the direction perpendicular to the upper surface of the substrate 100 (the direction perpendicular to DR1 and DR2). That is, an area of the third semiconductor layer 130p may be smaller than an area of the first semiconductor layer 120p in the direction parallel to the upper surface of substrate 100.

A width of the third semiconductor layer 130p may be smaller than a width of the first semiconductor layer 120p and larger than a width of the first gate electrode 140p. For a case in which a side surface of the third semiconductor layer 130p is formed to be tapered, a width d2 of a lower surface of the third semiconductor layer 130p may be smaller than a width of an upper surface of the first semiconductor layer 120p with which the lower surface of the third semiconductor layer 130p is in contact and larger than or equal to a width of an upper surface of the first channel region 121p. A width d1 of an upper surface of the third semiconductor layer 130p may be larger than or equal to a width of the first gate electrode 140p. The third semiconductor layer 130p may not overlap with the first source electrode 153p and the first drain electrode 154p.

The third semiconductor layer 130p may serve as a protective layer that protects the first channel region 121p of the first semiconductor layer 120p because the width of the third semiconductor layer 130p is formed to correspond to the first channel region 121p of the first semiconductor layer 120p. For example, the third semiconductor layer 130p may prevent hydrogen from directly flowing into the first channel region 121p of the first semiconductor layer 120p when the first gate insulating layer 112p is formed.

In some aspects, in the case of the display device 10, the length or width of the first channel region 121p of the first semiconductor layer 120p may be prevented from being formed differently from what was desired because the side surface of the third semiconductor layer 130p has an inclined surface corresponding to a side surface of the first gate electrode 140p and the lower surface of the third semiconductor layer 130p is larger than the first channel region 121p.

In some aspects, in the case of the display device 10, the first gate insulating layer 112p may be placed between the third semiconductor layer 130p and the first gate electrode 140p. The first gate insulating layer 112p may be patterned in a shape corresponding to the first gate electrode 140p, but is not limited thereto, and the first gate insulating layer 112p may also be formed to cover all of the buffer layer 111, the first semiconductor layer 120p, and the third semiconductor layer 130p.

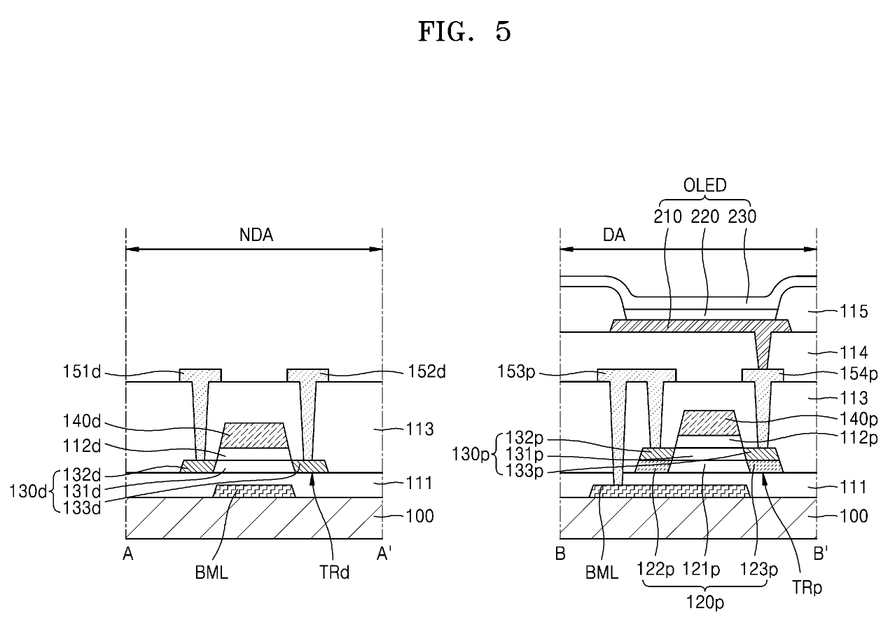

FIG. 5 is a cross-sectional view of a display device 10 according to another embodiment. A first thin film transistor TRp of the display device 10 of FIG. 5 is different from the first thin film transistor TRp of the display device 10 of FIG. 3. Below, the differences mentioned above will be explained, and any duplicate explanations will be omitted.

Referring to FIG. 5, the first thin film transistor TRp may include the first semiconductor layer 120p, the first gate electrode 140p, the first source electrode 153p, the first drain electrode 154p, and a third semiconductor layer 130p.

The third semiconductor layer 130p may be formed on the first semiconductor layer 120p. The third semiconductor layer 130p may include an oxide semiconductor material. The third semiconductor layer 130p may be formed amorphously. In an embodiment, the third semiconductor layer 130p may be formed of a same material as the second semiconductor layer 130d of the second thin film transistor TRd. The second semiconductor layer 130d and the third semiconductor layer 130p may be formed of a same material at a same process.

The third semiconductor layer 130p may be formed to overlap the first semiconductor layer 120p. In other words, the third semiconductor layer 130p may be formed on the first semiconductor layer 120p to cover the entire first semiconductor layer 120p.

The third semiconductor layer 130p may include a third channel region 131p, a third source region 132p connected to a side of the third channel region 131p, and a third drain region 133p connected to another side of the third channel region 131p. The third source region 132p and the third drain region 133p may be formed by selective conductivity of amorphous oxide semiconductor material, and the third channel region 131p may be a non-conductive portion. The third channel region 131p may overlap the first channel region 121p, and the third source region 132p and the third drain region 133p may overlap the first source region 122p and first drain region 123p, respectively.

The third channel region 131p of the third semiconductor layer 130p may have a higher carrier concentration than the first channel region 121p of the first semiconductor layer 120p.

The first gate electrode 140p may overlap both the first channel region 121p and the third channel region 131p. The first source electrode 153p and the first drain electrode 154p may be connected to the third source region 132p and the third drain region 133p, respectively. The first source electrode 153p and the first drain electrode 154p may transmit electrical signals to the first channel region 121p and the third channel region 131p.

The first gate insulating layer 112p may be placed between the third semiconductor layer 130p and the first gate electrode 140p. The first gate insulating layer 112p may be patterned in a shape corresponding to the first gate electrode 140p, but is not limited thereto, and the first gate insulating layer 112p may also be formed to cover all of the buffer layer 111, the first semiconductor layer 120p, and the third semiconductor layer 130p.

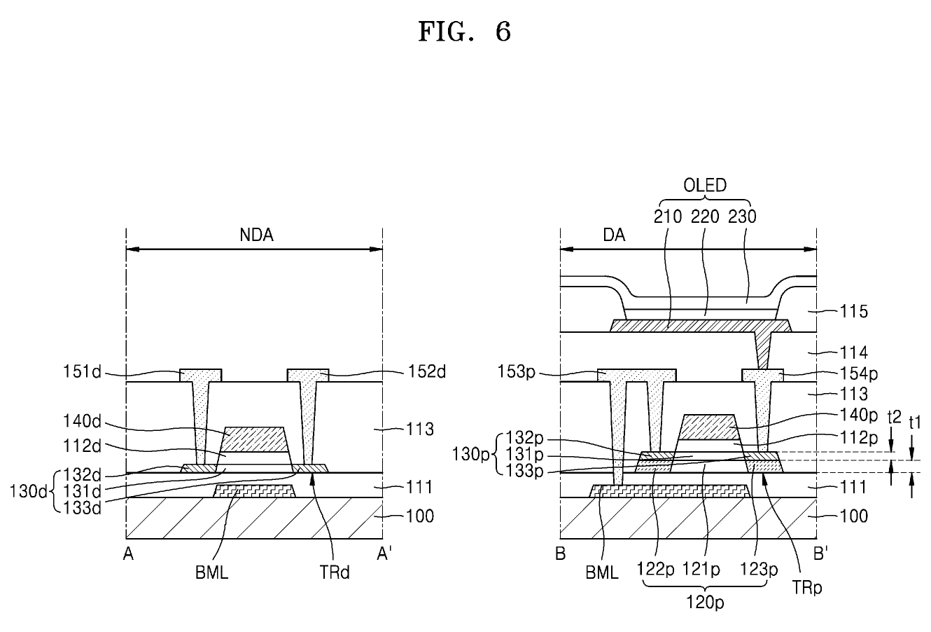

FIG. 6 is a cross-sectional view of a display device 10 according to another embodiment.

A thickness of a third semiconductor layer 130p of the first thin film transistor TRp and a thickness of a second semiconductor layer 130d of the second thin film transistor TRd of the display device 10 of FIG. 6 are different from those of the display device 10 of FIG. 5. Below, the differences mentioned above will be explained, and any duplicate explanations will be omitted.

Referring to FIG. 6, a thickness t2 of the third semiconductor layer 130p may be smaller than a thickness t1 of the first semiconductor layer 120p. The third semiconductor layer 130p may be formed of a same material at a same process as the second semiconductor layer 130d, and the second semiconductor layer 130d and the third semiconductor layer 130p may have a same thickness. That is, a thickness of the second semiconductor layer 130d is formed to be smaller than the thickness of the first semiconductor layer 120p when the second semiconductor layer 130d is formed in a same layer (e.g., buffer layer 111) as the first semiconductor layer 120p, such that the thickness t2 of the third semiconductor layer 130p may be smaller than the thickness t1 of the first semiconductor layer 120p.

However, embodiments of the present disclosure are not limited thereto, and the thickness t2 of the third semiconductor layer 130p may be greater than the thickness t1 of the first semiconductor layer 120p.

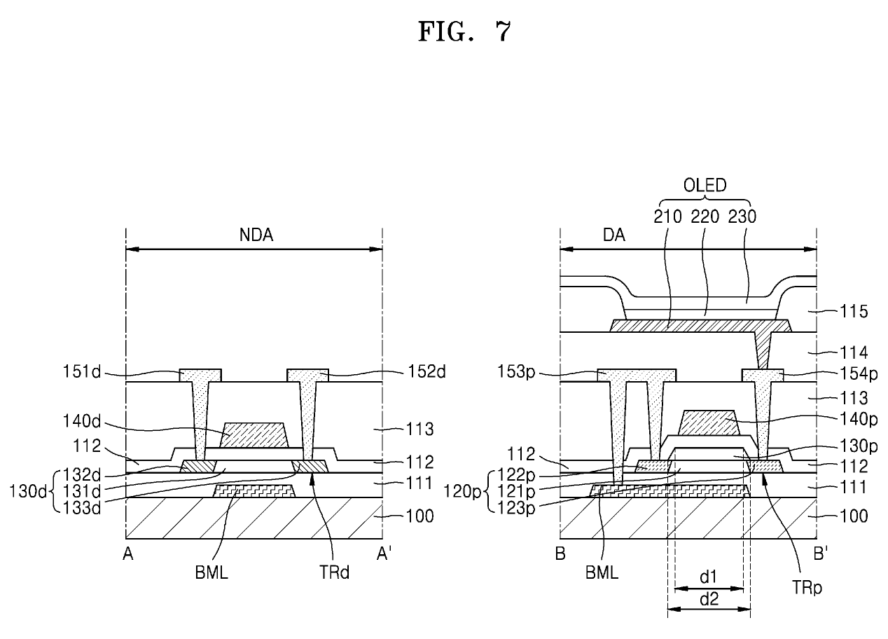

FIG. 7 is a cross-sectional view of a display device 10 according to another embodiment. A gate insulating layer 112 of the display device 10 of FIG. 7 is different from the gate insulating layer 112 of the display device 10 of FIG. 4. Below, the differences mentioned above will be explained, and any duplicate explanations will be omitted.

Referring to FIG. 7, the gate insulating layer 112 may be formed to cover the first semiconductor layer 120p and the third semiconductor layer 130p of the first thin film transistor TRp and the second semiconductor layer 130d and the buffer layer 111 of the second thin film transistor TRd. In this case, each of the first source electrode 153p, the first drain electrode 154p, the second source electrode 151d, and the second drain electrode 152d may penetrate the gate insulating layer 112 and be connected to the first semiconductor layer 120p or the second semiconductor layer 130d.

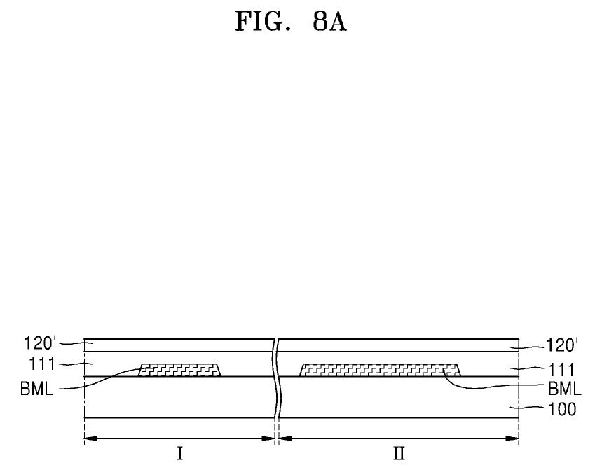

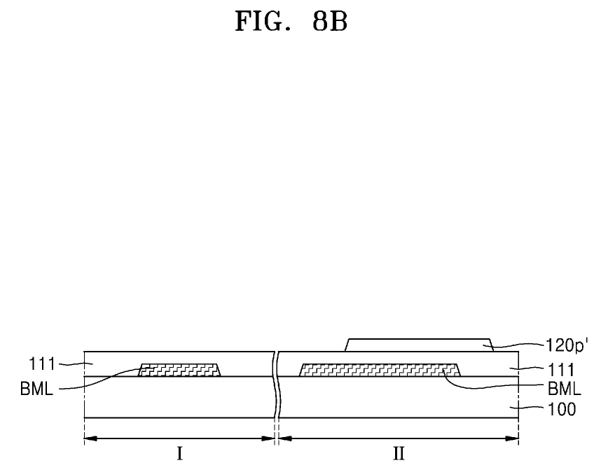

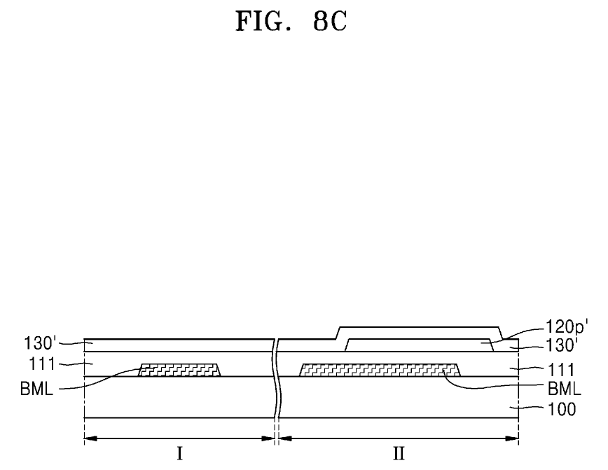

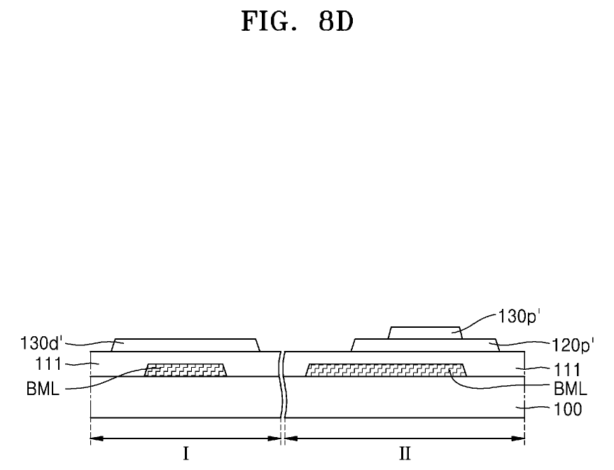

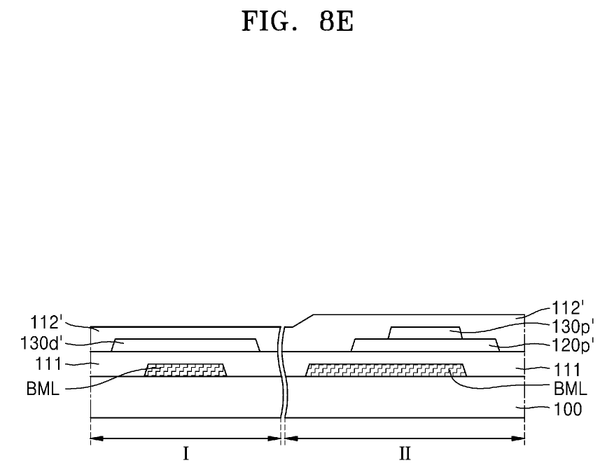

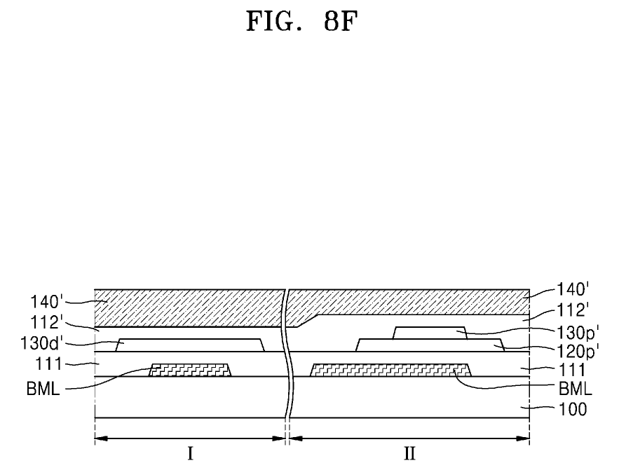

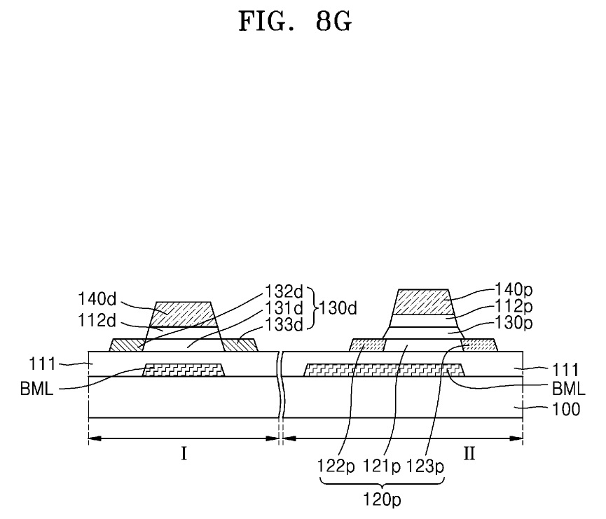

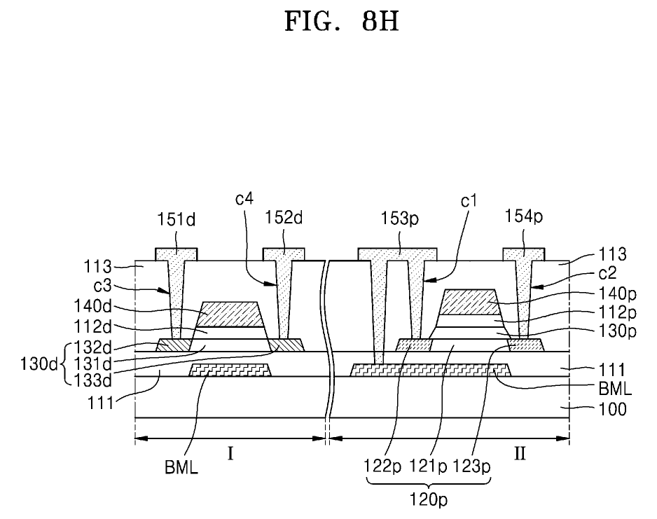

Hereinafter, a method of manufacturing the display device 10 according to an embodiment will be described with reference to FIGS. 8A to 8H. A first region I in FIGS. 8A to 8H may be a region where the second thin film transistor TRd is formed and may correspond to the non-display area NDA of FIGS. 3 to 7. A second region II may be a region where the first thin film transistor TRp is formed, and may correspond to the display area DA of FIGS. 3 to 7.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” “may be patterned,” and the like include methods, processes, and techniques for disposing, forming, patterning the element, and the like in accordance with example aspects described herein.

First, referring to FIG. 8A, in the method of manufacturing the display device 10 according to an embodiment, a first semiconductor material layer 120’ is formed on the substrate 100 on which the lower metal layer BML and the buffer layer 111 are formed. The first semiconductor material layer 120’ may be formed on the buffer layer 111 and may be formed on both the first region I and the second region II.

The first semiconductor material layer 120’ may include a crystalline oxide semiconductor material and may be formed as a thin film. The first semiconductor material layer 120’ may be formed by a sputtering method or a vapor deposition method such as a pulse laser deposition method, or the like.

Next, as illustrated in FIG. 8B, the first semiconductor material layer 120’ is patterned to form a first semiconductor pattern 120p’. The patterning may be performed by wet etching using an acid solution such as a mixture of hydrochloric acid, nitric acid, diluted sulfuric acid, phosphoric acid, and acetic acid, and performed after forming a photoresist pattern on the first semiconductor material layer 120’ corresponding to a portion where the first semiconductor layer 120p is to be formed. Of course, dry etching or a combination of dry etching and wet etching may also be used.

Next, the first semiconductor pattern 120p’ is heat treated such that the first semiconductor pattern 120p’ becomes a crystalline semiconductor pattern. The heat treatment of the first semiconductor pattern 120p’ may use a temperature of 350 °C or higher, and oxygen may be injected during the heat treatment process.

Next, a second semiconductor material layer 130’ is formed above the first semiconductor pattern 120p’ as illustrated in FIG. 8C. The second semiconductor material layer 130’ may be formed in both the first region I and the second region II. That is, the second semiconductor material layer 130’ may be formed on the buffer layer 111 in the first region I and laminated onto the first semiconductor pattern 120p’ in the second region II.

Next, as illustrated in FIG. 8D, the second semiconductor material layer 130’ is patterned to form a second semiconductor pattern 130d’ and a third semiconductor pattern 130p’. The patterning of the second semiconductor material layer 130’ may be performed by forming a photoresist pattern corresponding to a portion where the second semiconductor layer 130d will be formed and a portion where the third semiconductor layer 130p will be formed, and then by an etching process. That is, the second semiconductor pattern 130d’ and the third semiconductor pattern 130p’ may be formed simultaneously.

The patterning process of the second semiconductor material layer 130’ may be performed after crystallization of the first semiconductor pattern 120p’. Accordingly, the first semiconductor pattern 120p’ may be stably maintained even when the second semiconductor material layer 130’ is patterned.

In an embodiment, the third semiconductor layer 130p may not be formed on the first semiconductor layer 120p by not forming the third semiconductor pattern 130p’ corresponding to the third semiconductor layer 130p when patterning the second semiconductor material layer 130’.

Next, as illustrated in FIGS. 8E and 8F, a gate insulating material layer 112’, which covers the first semiconductor pattern 120p’, the second semiconductor pattern 130d’ and the third semiconductor pattern 130p’, and a gate electrode material layer 140’ are formed on the buffer layer 111.

The gate insulating material layer 112' may include an inorganic material such as silicon oxide, silicon nitride, and/or silicon oxynitride, and may be formed through chemical vapor deposition (CVD) or atomic layer deposition (ALD).

The gate electrode material layer 140' may include molybdenum (Mo), aluminum (Al), copper (Cu), and/or titanium (Ti), and may be formed as a single-film or multilayer film. The gate electrode material layer 140' may be formed by a deposition method such as chemical vapor deposition, plasma enhanced chemical vapor deposition (PECVD), low pressure chemical vapor deposition (LPCVD), physical vapor deposition (PVD), sputtering, and atomic layer deposition (ALD), but is not limited thereto.

Next, as illustrated in FIG. 8G, the gate insulating material layer 112' and the gate electrode material layer 140' are patterned to form the first gate electrode 140p, the first gate insulating layer 112p, the second gate electrode 140d, and the second gate insulating layer 112d. In an embodiment, the gate insulating material layer 112' may not be patterned when the gate electrode material layer 140' is patterned, and the gate insulating material layer 112' may form one gate insulating layer 112 spanning the first region I and the second region II.

Next, impurities are doped into the first semiconductor pattern 120p’ and the second semiconductor pattern 130d’ to form the first semiconductor layer 120p and the second semiconductor layer 130d. The first semiconductor layer 120p may be formed by injecting impurities into the first source region 122p and the first drain region 123p, excluding the first channel region 121p, and the second semiconductor layer 130d may be formed by injecting impurities into the second source region 132d and the second drain region 133d, excluding the second channel region 131d.

The third semiconductor pattern 130p’ forms the third semiconductor layer 130p. In an embodiment, the width of the third semiconductor layer 130p may correspond to the width of the first channel region 121p. In this case, the third semiconductor layer 130p may act as a mask to protect the first channel region 121p when doping the first semiconductor layer 120p.

Next, as illustrated in FIG. 8H, the interlayer insulating layer 113 is formed over the entire surface of the buffer layer 111 on the first gate electrode 140p and the second gate electrode 140d, a first through hole c1 exposing the first source region 122p of the first semiconductor layer 120p, a second through hole c2 exposing the first drain region 123p, a third through hole c3 exposing the second source region 132d of the second semiconductor layer 130d and a fourth through hole c4 exposing the second drain region 133d are formed by penetrating the interlayer insulating layer 113, and the first source electrode 153p, the first drain electrode 154p, the second source electrode 151d and the second drain electrode 152d are formed on the interlayer insulating layer 113.

The first source electrode 153p, the first drain electrode 154p, the second source electrode 151d and the second drain electrode 152d may be formed by forming a conductive material layer through various deposition methods such as chemical vapor deposition, plasma enhanced chemical vapor deposition (PECVD), low pressure chemical vapor deposition (LPCVD), physical vapor deposition (PVD), sputtering and atomic layer deposition (ALD), and then by patterning the conductive material layer.

The display device 10 may be applied to various electronic devices. An electronic device according to an embodiment includes the display device 10 described herein, and may further include a module or device having additional functions in addition to the display device 10.

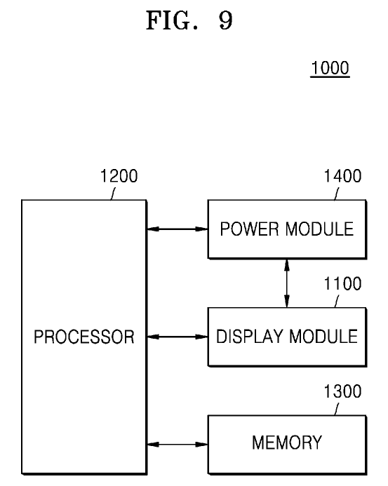

FIG. 9 is a block diagram of an electronic device 1000 according to an embodiment. Referring to FIG. 9, the electronic device 1000 may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The memory 1300 may store data information supportive of the operation of the processor 1200 or display module 1100. Image data signals and/or input control signals are transmitted to the display module 1100 when the processor 1200 executes an application stored in the memory 1300, and the display module 1100 may process the received signals and output image information through the display screen.

The power module 1400 may include a power supply module such as a power adapter or a battery device, and a power conversion module that converts power supplied by the power supply module to generate power supportive of the operation of the electronic device 1000.

At least one of the components of the electronic device 1000 described herein may be included in the display device according to the embodiments described herein. In some aspects, some of individual modules that are functionally included within a single module may be included within the display device and others may be provided separately from the display device. For example, the display device may include the display module 1100, while the processor 1200, the memory 1300 and the power module 1400 may be provided in a form of other devices within the electronic device 1000 other than the display device.

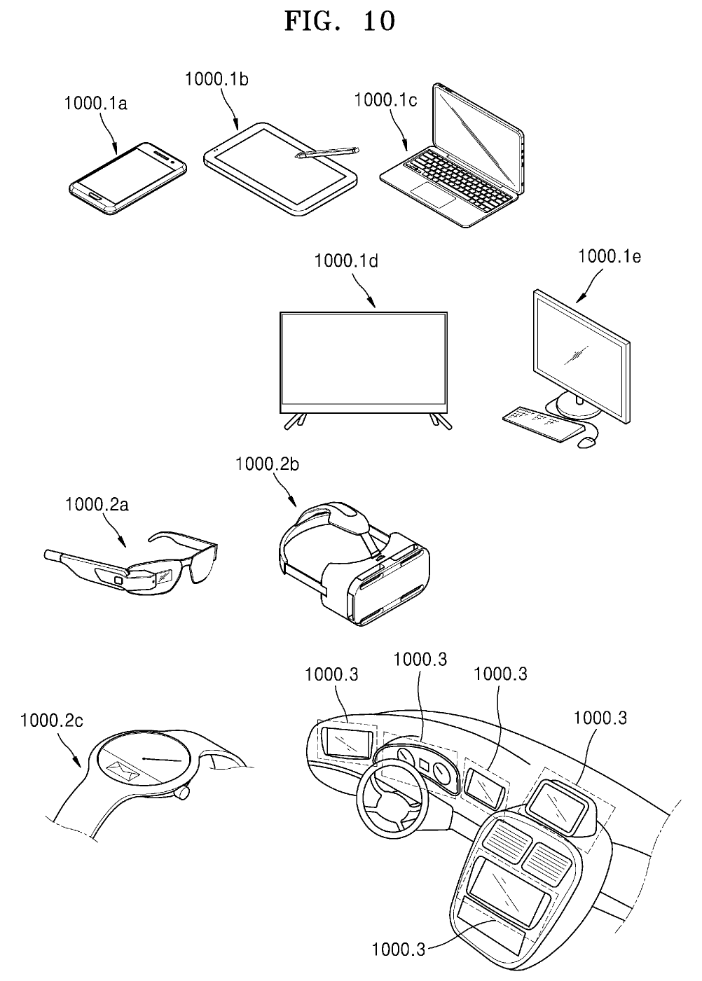

FIG. 10 is a schematic diagram of electronic devices according to various embodiments.

Referring to FIG. 10, various electronic devices to which the display device according to embodiments are applied may include not only electronic devices for displaying images such as smart phones 1000_1a, tablet personal computers 1000_1b, laptops 1000_1c, TVs 1000_1d and desk monitors 1000_1e, but also wearable electronic devices including display modules such as smart glasses 1000_2a, head-mounted displays 1000_2b and smart watches 1000_2c, electronic devices for vehicles 1000_3 including display modules such as center information displays (CIDs) arranged on instrument panels, center fascias and dashboards of automobiles, and room mirror displays, or the like.

As described herein, in the case of the display device 10 and the electronic device 1000 according to the embodiments, the first thin film transistor TRp including the first semiconductor layer 120p including the crystalline oxide semiconductor is arranged in the driving transistor of the pixel circuit, and the second thin film transistor TRd including the second semiconductor layer 130d including the amorphous oxide semiconductor is arranged in the output transistor of the driving circuit, such that the characteristics of the driving transistor of the pixel circuit and the output transistor of the driving circuit may be selectively improved, and the electrical characteristics and the driving stability may be improved.

In some aspects, in the case of the display device 10 and the electronic device 1000 according to the embodiments, process stability may be improved and process cost and time may be reduced. The embodiments may improve electrical characteristics and enhance the reliability of the manufacturing process by implementing the driving thin film transistor of the pixel circuit and the buffer transistor of the driving circuit to include different oxide semiconductor layers. However, the effects are not limited to the above, and may be expanded in various ways without departing from the spirit and scope of the embodiments.

Each of the embodiments described herein can be implemented independently, but it goes without saying that the structure of each embodiment can be applied in combination to other embodiments.

Although the embodiments have been described with reference to the drawings, they are examples, and those skilled in the art will understand that various modifications and equivalent other embodiments are possible therefrom. Accordingly, the technical protection scope of the embodiments should be determined by the technical idea of the appended claims.

The specific implementations described in the examples are examples and do not limit the scope of the examples in any way. If there is no specific mention of an element as being “essential” or “important”, the element may not be a required component.

The use of the term “the” and similar referential terms in the specification of embodiments (especially in the claims) may refer to both the singular and the plural. If a range is described in an embodiment, it is considered that the invention includes an individual value that falls within the range (unless otherwise stated), and it is the same as describing each individual value that constitutes the range in the detailed description. Finally, unless there is an explicit description of the order or sequence of steps constituting a method according to an embodiment, the steps may be performed in any suitable order. The examples are not necessarily limited to the order in which the above steps are described. Any use of examples or exemplary terms in the embodiments is intended to elaborate the embodiments and is not intended to limit the scope of the embodiments, unless otherwise defined by the claims. Furthermore, those skilled in the art will appreciate that various modifications, combinations and variations can be made according to design conditions and factors within the scope of the appended claims or their equivalents.

What is claimed is:

1. A display device comprising:
a substrate comprising a display area and a non-display area surrounding the display area;
a pixel circuit overlapping the display area and comprising a first thin film transistor comprising a first semiconductor layer and a first gate electrode; and
a driving circuit connected to the pixel circuit, overlapping the non-display area, and comprising a second thin film transistor comprising a second semiconductor layer and a second gate electrode,
wherein:
the first semiconductor layer comprises a first oxide semiconductor material,
the second semiconductor layer comprises a second oxide semiconductor material, and
an electron mobility of the second thin film transistor is higher than an electron mobility of the first thin film transistor.

2. The display device of claim 1, wherein:
the first semiconductor layer comprises a crystalline oxide semiconductor material, and
the second semiconductor layer comprises an amorphous oxide semiconductor material.

3. The display device of claim 1, wherein the first semiconductor layer and the second semiconductor layer are arranged in a same layer.

4. The display device of claim 1, wherein the first thin film transistor further comprises a third semiconductor layer disposed on the first semiconductor layer.

5. The display device of claim 4, wherein the third semiconductor layer and the second semiconductor layer comprise a same material.

6. The display device of claim 4, wherein:
the third semiconductor layer comprises an amorphous oxide semiconductor material, and
the first semiconductor layer comprises a crystalline oxide semiconductor material.

7. The display device of claim 4, wherein the third semiconductor layer overlaps the first semiconductor layer.

8. The display device of claim 4, wherein a width of the third semiconductor layer is smaller than a width of the first semiconductor layer.

9. The display device of claim 4, wherein a thickness of the third semiconductor layer and a thickness of the first semiconductor layer are equal to each other.

10. The display device of claim 4, wherein:
a thickness of the third semiconductor layer and a thickness of the second semiconductor layer are equal to each other, and
the thickness of the second semiconductor layer is smaller than a thickness of the first semiconductor layer.

11. The display device of claim 4, wherein a width of the third semiconductor layer is smaller than a width of the first semiconductor layer and larger than a width of the first gate electrode.

12. The display device of claim 1, wherein the first thin film transistor is a driving thin film transistor of the pixel circuit.

13. The display device of claim 1, wherein:
each of the first semiconductor layer and the second semiconductor layer comprises indium (In), and
an indium content of the first semiconductor layer is greater than an indium content of the second semiconductor layer.

14. A display device comprising:
a substrate comprising a display area and a non-display area surrounding the display area;
a pixel circuit overlapping the display area; and
a light-emitting element electrically connected to the pixel circuit and generating light,
wherein the pixel circuit comprises:
a driving transistor comprising a drain electrode connected to a first node, a gate electrode connected to a second node, and a source electrode connected to a third node;
a switching transistor applying a data signal to the first node in response to a scan signal; and
an initialization transistor applying an initialization voltage to the second node in response to an initialization control signal, and
the driving transistor comprises a first semiconductor layer comprising a crystalline oxide semiconductor material.

15. The display device of claim 14, wherein:
the first semiconductor layer comprises indium (In), and
an indium content of the first semiconductor layer is greater than or equal to 80 at%.

16. The display device of claim 14, wherein:
the driving transistor further comprises a third semiconductor layer arranged on the first semiconductor layer, and
the third semiconductor layer comprises an amorphous oxide semiconductor material.

17. The display device of claim 14, further comprising:
a driving circuit overlapping the non-display area and comprising an output transistor, and
wherein the output transistor comprises a second semiconductor layer comprising an amorphous oxide semiconductor material.

18. An electronic device comprising a display device,
wherein the display device comprises:
a substrate comprising a display area and a non-display area surrounding the display area;
a pixel circuit overlapping the display area and comprising a first thin film transistor comprising a first semiconductor layer and a first gate electrode; and
a driving circuit connected to the pixel circuit, overlapping the non-display area, and comprising a second thin film transistor comprising a second semiconductor layer and a second gate electrode,
wherein:
the first semiconductor layer comprises a first oxide semiconductor material,
the second semiconductor layer comprises a second oxide semiconductor material, and
an electron mobility of the second thin film transistor is higher than an electron mobility of the first thin film transistor.

19. The electronic device of claim 18, wherein:
the first semiconductor layer comprises a crystalline oxide semiconductor material, and
the second semiconductor layer comprises an amorphous oxide semiconductor material.

20. The electronic device of claim 19, wherein the first semiconductor layer and the second semiconductor layer are arranged in a same layer.
